(19) United States
(12) Patent Application Publication
(10) Pub. No.: US 2016/0061173 A1
(43) Pub. Date: Mar. 3, 2016

(54) SYSTEM AND METHOD FOR DETERMINING HEALTH OF AN ENGINE-GENERATOR SET

(71) Applicant: General Electric Company, Schenectady, NY (US)

(72) Inventors: Christopher James Chuah, Clifton Park, NY (US); Shanon Kolasienski, Glens Fall, NY (US); David E. James, Clifton Park, NY (US)

(21) Appl. No.: 14/469,654

(22) Filed: Aug. 27, 2014

(51) Int. Cl. F02N 11/08; F02B 77/08; G01R 31/36

(52) U.S. Cl. CPC F02N 11/0848; G01R 31/362; F02B 77/084

(57) ABSTRACT

The present disclosure is directed to systems and methods for determining health of an engine-generator set of a hybrid power system having at least one battery power source. For example, in one embodiment, a battery management system sends a start-up command to the engine-generator set. After sending the command, at least one start-up condition (e.g. a start-up time lapse, a start-up voltage parameter of a starter battery of the engine-generator set, or a voltage of the battery power source before sending the start-up command) is determined for the hybrid power system. Next, a start-up condition trend is generated based on a plurality of the start-up conditions over multiple start-ups. Thus, the engine-generator set health can be determined based on a comparison of the start-up condition trend and a threshold start-up condition for the engine-generator set.

### FIELD OF THE INVENTION

The present disclosure relates generally to engine-generator sets, and more particular to a system and method for determining the health of an engine-generator set.

### BACKGROUND OF THE INVENTION

Typically, the primary source of electrical power for a consuming entity, e.g. a telecommunications facility, is commercial power from a utility. However, for an off-grid or weak-grid telecom facility, the main power source may include an engine-generator set, e.g. a diesel generator, and a plurality of batteries that can be used in backup situations. For example, if power from the commercial utility is lost, the diesel generator can be activated to supply power to the telecom facility. Start-up of the diesel generator, however, takes time; therefore, the batteries provide power during this transitional time period. If the diesel generator fails to start (e.g., runs out of fuel, suffers a mechanical failure), then the batteries are able to provide power for an additional period of time. Though diesel generators are inexpensive to install, the escalating cost of diesel fuel, and its delivery to remote locations, has driven the search for alternative, economical solutions.

For example, certain telecom facilities employ a diesel-battery hybrid power system to conserve fuel where the primary power source is a diesel generator. In such a scenario, a long, life-cycle battery is used to alternately share the site load with the diesel generator. More specifically, during operation, the diesel generator is modulated on and off and, when it is active, powers the facility and recharges the battery at an overall higher efficiency than if powering the facility alone. Once the battery is recharged, the generator can be turned off and the battery is used to sustain the facility load. Such hybrid power systems have achieved fuel savings of up to 50% in some applications.

One issue with converting sites that run purely on diesel generators to hybrid diesel-battery operation, however, is the reliability of the diesel generator. Thus, it would be advantageous to provide a system and method for monitoring or tracking the diesel generator health and proactively ensuring that the diesel generator operates when it should.

### BRIEF DESCRIPTION OF THE INVENTION

Aspects and advantages of the invention will be set forth in part in the following description, or may be obvious from the description, or may be learned through practice of the invention.

One example aspect of the present disclosure is directed to a method for determining the health of an engine-generator set of a hybrid power system comprising at least one battery power source. For example, in another embodiment, the battery power source may include one or more sodium nickel chloride batteries. The method includes sending, by a battery management system, a start-up command to the engine-generator set. After sending the start-up command, another step includes determining at least one start-up condition of the hybrid power system. The method also includes generating a start-up condition trend based on a plurality of the start-up conditions of the hybrid power system over multiple start-ups. Thus, a further step includes determining the health of the engine-generator set based on the comparison and the start-up condition trend and a threshold start-up condition for the engine-generator set.

In one embodiment, the start-up condition of the hybrid power system may include a start-up time lapse, a start-up voltage parameter of a starter battery of the engine-generator set, a voltage of at least one battery power source before sending the start-up command to the engine-generator set, or any other suitable start-up condition. For example, in certain embodiments, the start-up time lapse may be a time lapse between sending the start-up command and actual start-up of the engine-generator set. Alternatively, the start-up time lapse may be a predetermined monitoring time period, such as for example, a time period between before the start-up command is sent to the engine-generator set and the actual start-up of the engine-generator set. In another embodiment, the method further includes a step of indicating to a user, by the battery management system, that the engine-generator set health is poor if the start-up time lapse is greater than a threshold start-up time and indicating to the user, by the battery management system, that the engine-generator set health is good if the start-up time lapse is less than the threshold start-up time.

In a further embodiment, the method includes indicating to a user, by the battery management system, that the engine-generator set health is good if the start-up voltage parameter is above a threshold voltage and indicating to the user, by the battery management system, that the engine-generator set health is poor if the start-up voltage parameter is below the threshold voltage.

In still another embodiment, the method includes indicating to a user, by the battery management system, that the engine-generator set health is good if the voltage of the starter battery of the engine-generator set, before sending the start-up command to the engine-generator set, is above a threshold voltage and indicating to a user, by the battery management system, that the engine-generator set health is poor if the voltage of the starter battery of the engine-generator set, before sending the start-up command to the engine-generator set, is below the threshold voltage.

In a further embodiment, the step of determining the start-up time lapse between sending the start-up command and actual start-up of the engine-generator set may include determining a time between sending the start-up command and a time at which one or more batteries of the battery management system begins receiving a charge. In additional embodiments, the at least one battery power source may include one or more sodium nickel chloride batteries.

In another aspect, the present disclosure is directed to a method for determining the health of an engine-generator set of a hybrid power system having at least one battery power source. The method includes sending, by a battery management system, a charging command to the engine generator set. Another step includes determining a voltage condition of the starter battery of the engine-generator set. In certain embodiments, the voltage condition may be determined before, during, or after sending the charging command to the engine-generator set. In addition, the voltage condition may be determined while the engine-generator set is trying to start. Still another step of the method includes monitoring, via a battery management system, a voltage trend of the starter battery based on a plurality of voltage conditions of the starter battery over a predetermined time period. Thus, the health of the engine-generator set can be determined based on the voltage trend or the voltage when discharge of the starter battery of the engine-generator set has stopped and the engine-generator set is on.

In one embodiment, after sending the charging command to the engine-generator set, the method may also include determining whether the starter battery of the engine-generator set initially begins to charge. Thus, if the starter battery of the engine-generator set initially begins to charge, the method may further include indicating to a user, by the battery management system, that the engine-generator set starting health is good. Alternatively, if the starter battery set does not initially begin to charge, the method may include indicating to the user, by the battery management system, that the engine-generator set health is poor.

In still a further embodiment, if the starter battery of the engine-generator set initially begins to charge, the method may also include continuously monitoring the charge trend of the starter battery of the engine-generator set. Thus, if the starter battery of the engine-generator set continues to charge, the method may include indicating to a user, by the battery management system, that the engine-generator set starting health is good. Alternatively, if the starter battery set does not continue to charge, the method may include indicating to the user, by the battery management system, that the engine-generator set starting health is poor.

In certain embodiments, the step of determining the voltage condition of the starter battery of the engine-generator set may include determining a load of the engine-generator set. The method also includes monitoring an energy storage capacity of the battery power source.

In yet another aspect, the present disclosure is directed to a method for determining other aspects of the health of an engine-generator set of a hybrid power system comprising at least one battery power source. The method includes sending, by a battery management system, a start-up command to the engine-generator set. Another step includes determining a fuel consumption trend of the engine-generator set as a function of at least one of a site load for the hybrid power system during charge of the battery power source or a total operating time of the engine-generator set for a predetermined time period. Thus, the method also includes determining health of the engine-generator set based on the fuel consumption trend.

In another embodiment, the method may also include a step of comparing the fuel consumption trend to a threshold fuel consumption value. Thus, in certain embodiments, if the fuel consumption trend is equal to or greater than the threshold fuel consumption value, then the method may include indicating to a user, by the battery management system, that the engine-generator set health is good. Alternatively, if the fuel consumption trend is less than the threshold fuel consumption value, the method may also include indicating to the user, by the battery management system, that the engine-generator set health is poor.

In still another embodiment, the step of indicating, by the battery management system, that the engine-generator set is poor, implies at least one of fuel leakage from the engine-generator set or fuel theft. For example, in one embodiment, if the engine-generator set shuts off and the battery power source stops charging before a predetermined charge time, then the engine-generator set may be out of fuel or may have failed.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1 illustrates a schematic diagram of one embodiment of a hybrid generator-battery power system for a telecommunications application;

FIG. 2 illustrates a block diagram of one embodiment of a battery management system (BMS) according to the present disclosure;

FIG. 3 illustrates a block diagram of one embodiment of a system for determining engine-generator set health according to the present disclosure;

FIG. 4 illustrates a graph of one embodiment of a start-up voltage parameter trend for a properly operating engine-generator set according to the present disclosure;

FIG. 5 illustrates a graph of one embodiment of a start-up voltage parameter trend for an improperly operating engine-generator set according to the present disclosure; and

FIG. 6 illustrates a flow diagram of one embodiment of a method for determining engine-generator set health according to the present disclosure.

### DETAILED DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

Generally, the present disclosure is directed to systems and methods for determining health of an engine-generator set (EGS), e.g. a diesel generator, of a hybrid power system having at least one battery power source so as to proactively ensure that the EGS operates when required. More specifically, in one embodiment, a battery management system (BMS) sends a start-up command to the EGS. After sending the start-up command, a controller is configured to determine at least one start-up condition (e.g. a start-up time lapse, a start-up voltage parameter of a starter battery of the EGS, or a voltage of the battery power source before sending the start-up command) of the hybrid power system. Thus, the controller can generate a start-up condition trend based on a plurality of the start-up conditions of the hybrid power system over multiple start-ups. Accordingly, EGS health can be determined based on a comparison of the start-up condition trend and a threshold start-up condition for the EGS.

In an alternative embodiment, EGS health may be determined by sending, by the BMS, a charging command to the EGS and monitoring the voltage drop and charge of a starter battery of the engine-generator set thereafter. As such, the BMS may record a voltage drop or charge trend of the starter battery over a predetermined time period that indicates whether the starter battery is discharging as expected during the EGS start and charging (or not charging) when required. In still another embodiment, EGS health may be determined by sending, by the BMS, a start-up command to the EGS and determining a fuel consumption trend of the EGS as a function of a site load for the hybrid power system during charge of the battery power source, a total operating time of the engine-generator set for a predetermined time period, or both.

The present disclosure has many advantages not present in the prior art. For example, the present disclosure prevents site outages due to loss of EGS operation. In addition, the present disclosure is also configured to track the health of the EGS and proactively ensure that the generator operates when required. As such, the present disclosure is configured to infer whether the EGS is not operating properly and is heading towards failure and/or whether the EGS is not operating at all. Further, by utilizing the BMS, the present disclosure eliminates the need for separate EGS monitoring and diagnostic devices.

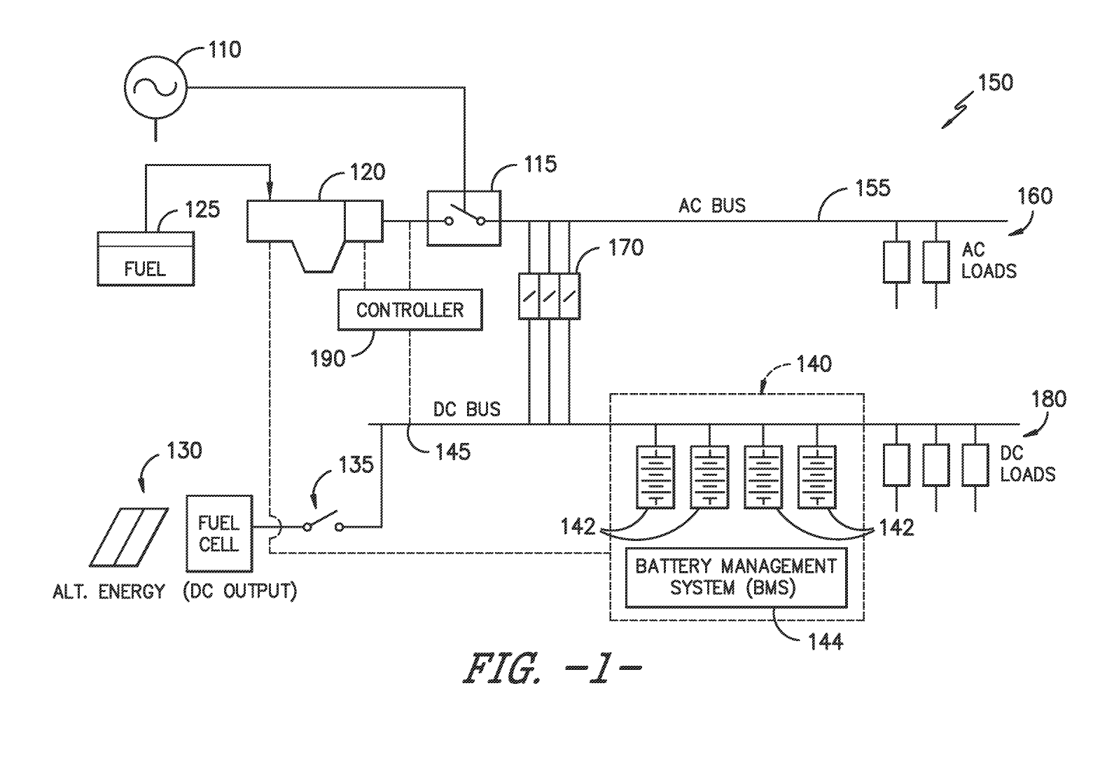

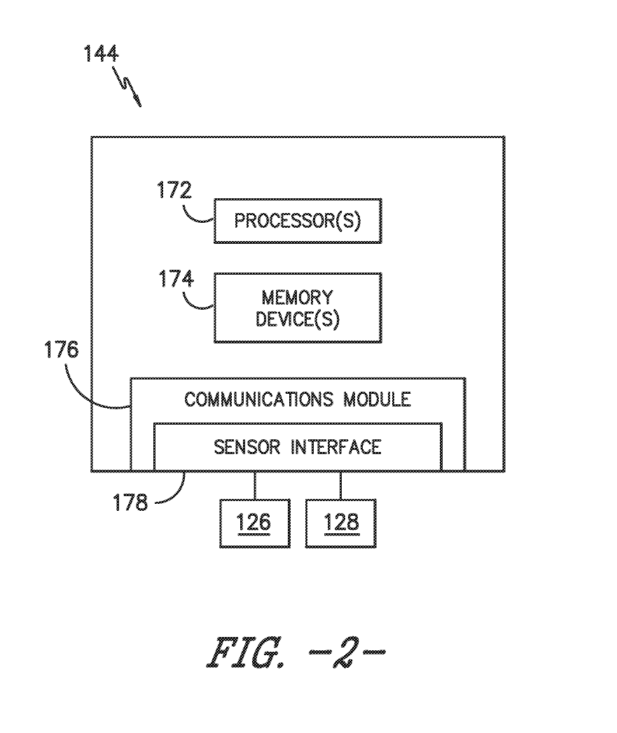

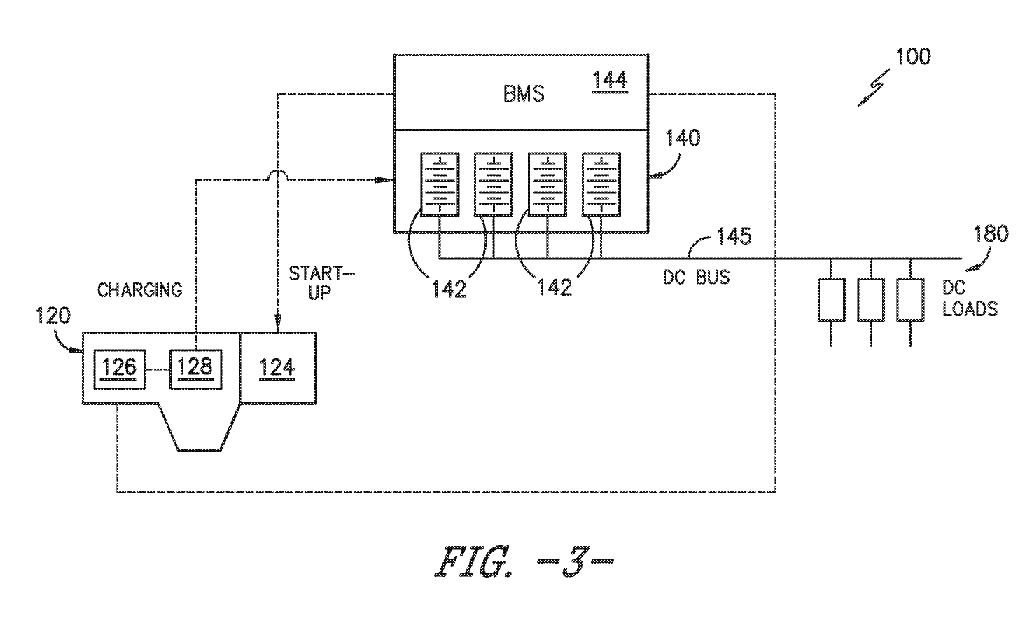

Referring generally to the drawings, FIG. 1 is an illustration of one embodiment of a hybrid generator-battery power system 150 for a telecom base transceiver station (BTS) configured to operate according to the present disclosure. FIG. 2 illustrates a block diagram of one embodiment of a battery management system (BMS) that can be part of the power system 150. FIG. 3 illustrates a simplified block diagram of a system 100 for determining health of the EGS 120 according to the present disclosure.

As shown, the illustrated embodiment depicts multiple sources of power including an AC power grid 100, an engine-generator power source or engine-generator set (EGS) 120 and a battery power source 140, which is an energy storage device (ESD). A transfer switch 115 allows transfer of operation between the AC grid power and the EGS 120, as well as other AC electrical power that may be available. The EGS 120 typically runs on fuel (e.g., diesel fuel) provided by a fuel source 125 (e.g., a storage tank). An availability switch 135 allows for alternate energy sources 130 (e.g. solar, wind, or fuel cell), if available, to be switched in to a DC bus 145 or an AC bus 155 of the power system 100 as well. If switching into the AC bus 155, an inverter 170 (described below) can be coupled between the alternate energy source 130 and the AC bus 155.

The battery power source 140 is an electrical power source. More specifically, in certain embodiments, the battery power source 140 may include one or more sodium nickel chloride batteries 142. Such batteries are particularly suitable due to their high charge acceptance that can drive the EGS 120 to peak efficiency, thereby reducing fuel costs for the BTS. In addition, battery performance, particularly its charge acceptance, is not affected by ambient temperature; therefore, such batteries can be used at sites with extreme temperature variations.

The AC bus 155 provides AC power to drive AC loads 160 of the system such as, for example, lighting and/or air conditioning of a telecom base transceiver station (BTS). Furthermore, the AC bus 155 can provide AC power to a rectifier 170 which converts AC power to DC power and provides the DC power to the DC bus 145 to drive DC loads 180 of the power system 150 such as the radios, switches, and amplifiers of the telecom base transceiver station (BTS). The DC bus 145 also provides DC power from the rectifier 170 to charge the battery power source 140 and provides DC power from the battery power source 140 to the DC loads 180 as the battery power source 140 discharges. A controller 190 may be configured to monitor and/or control various aspects of the system 150, such as commanding the engine of the EGS 120 to turn on or off in accordance with a control logic of the controller 190. In accordance with various embodiments, the controller 190 may be a separate unit or may be part of a battery management system (BMS) 144 of the battery power source 140.

The rectifier or regulator 170 may regulate DC power from a DC electrical power source (e.g., a solar energy system or a fuel cell energy system) instead of an AC electrical power source. The terms “rectifier” and “regulator” are used broadly herein to describe a device that conditions energy from a primary power source to provide DC electrical power to DC loads (e.g., DC loads 180) and to an ESD (e.g., the battery power source 140). In general, a primary power source may provide AC or DC electrical power that is used by an ESD (e.g., by the DC battery power source 140) of the power system 150.

During operation, when the EGS 120 is on, the EGS 120 provides power to the DC loads 180 and to the battery power source 140 during a charging part of the cycle. When the EGS 120 is off, the battery power source 140 provides power to the DC loads 180 during a discharging part of the cycle. The state of the battery power source 140 can be estimated by observations of the current of the battery power source 140. More specifically, the series or recharge resistance profile is learned or otherwise determined as a function of charge status. This characteristic is then monitored and updated as the battery power source 140 ages.

As shown particularly in FIGS. 1 and 3, the battery power source 140 may be controlled by the BMS 144. For example, in several embodiments, the BMS 144 is configured to monitor and/or control operation of the batteries 142. In addition, in accordance with the present disclosure, the BMS 144 may be configured to communicate with the EGS 120 by sending a start-up command to a starter battery 124 so as to start-up the engine of the EGS 120 in accordance with control logic of the BMS 144. The BMS 144 may also provide control logic for operation of any other components of the system 100. For example, the BMS 144 may be, for example, a logic controller implemented purely in hardware, a firmware-programmable digital signal processor, or a programmable processor-based software-controlled computer.

More particularly, as shown in FIG. 2, the BMS 144 can include any number of control devices. As shown, for example, the BMS 144 can include one or more processor(s) 172 and associated memory device(s) 174 configured to perform a variety of computer-implemented functions and/or instructions (e.g., performing the methods, steps, calculations and the like and storing relevant data as disclosed herein). The instructions when executed by the processor 172 can cause the processor 172 to perform operations, including providing control commands to the ESD 120 and/or other aspects of the system 100. Additionally, the BMS 144 may also include a communications module 176 to facilitate communications between the BMS 144 and the various components of the system 100. Further, the communications module 176 may include a sensor interface 178 (e.g., one or more analog-to-digital converters) to permit signals transmitted from one or more sensors 126, 128 to be converted into signals that can be understood and processed by the processors 172. It should be appreciated that the sensors (e.g. sensors 126, 128) may be communicatively coupled to the communications module 176 using any suitable means. For example, as shown in FIG. 2, the sensors 126, 128 are coupled to the sensor interface 178 via a wired connection. However, in other embodiments, the sensors 126, 128 may be coupled to the sensor interface 178 via a wireless connection, such as by using any suitable wireless communications protocol known in the art. As such, the processor 172 may be configured to receive one or more signals from the sensors 126, 128.

As used herein, the term “processor” refers not only to integrated circuits referred to in the art as being included in a computer, but also refers to a controller, a microcontroller, a microcomputer, a programmable logic controller (PLC), an application specific integrated circuit, and other programmable circuits. The processor 172 is also configured to compute advanced control algorithms and communicate to a variety of Ethernet or serial-based protocols (Modbus, OPC, CAN, etc.). Additionally, the memory device(s) 174 may generally comprise memory element(s) including, but not limited to, computer readable medium (e.g., random access memory (RAM)), computer readable non-volatile medium (e.g., a flash memory), a floppy disk, a compact disc-read only memory (CD-ROM), a magneto-optical disk (MOD), a digital versatile disc (DVD) and/or other suitable memory elements. Such memory device(s) 174 may generally be configured to store suitable computer-readable instructions that, when implemented by the processor(s) 172, configure the BMS 144 to perform the various functions as described herein.

Referring to FIG. 3, one embodiment of the system 100 for determining health of the EGS 120 of the hybrid power system 150 is illustrated. As shown, the system 100 is configured to send, by the BMS 144 a start-up or charging command to the starter battery 124 of the EGS 120. In addition, the system 100 may include one or more sensors 126, 128 in communication with the BMS 144. Thus, in one embodiment, after sending the start-up command to the starter battery 124 of the EGS 120, the BMS 144 is configured to monitor and/or determine a start-up condition of the hybrid power system 150. For example, in one embodiment, the sensors 126, 128 are configured to monitor any operational parameter(s), including start-up conditions, of the system 100. For example, in certain embodiments, the sensors 126, 128 are configured to monitor one or more start-up conditions of the hybrid power system 150, such as e.g. a start-up time lapse, a start-up voltage parameter of a starter battery 124 of the EGS 120, or a voltage of the one of the batteries 142 of the battery power source 140 before sending the start-up command to the EGS 120.

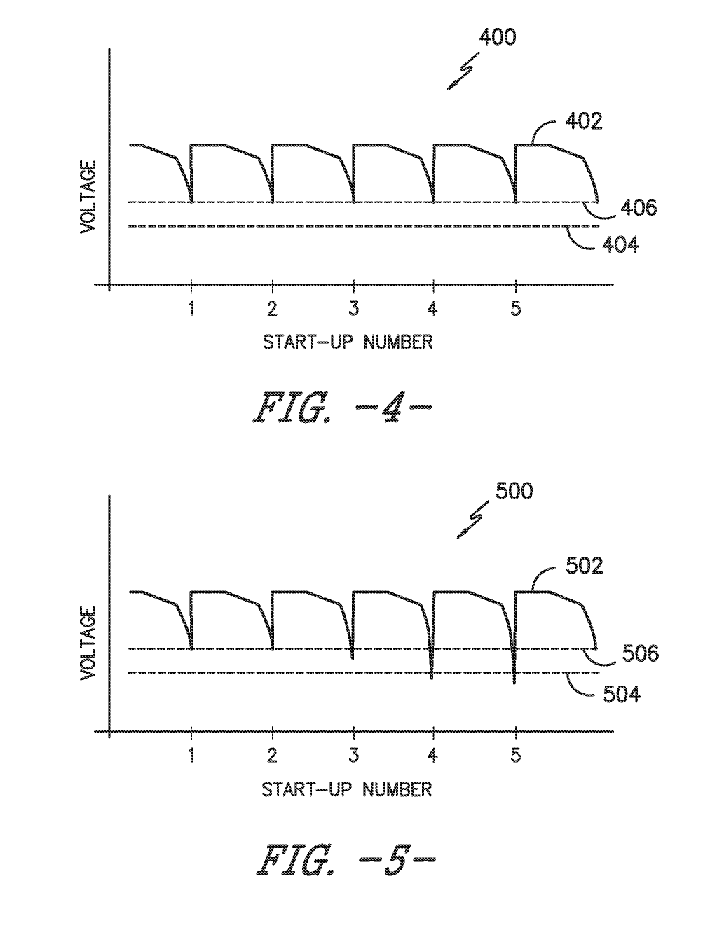

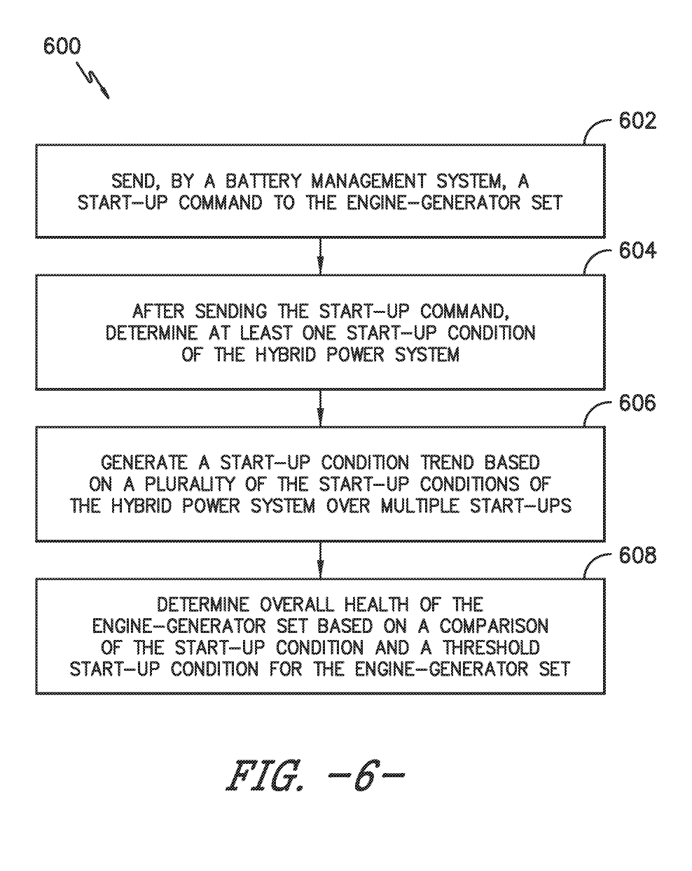

The processor 172 is then configured to generate a start-up condition trend based on a plurality of start-up conditions of the hybrid power system 150 over multiple start-ups. For example, in one embodiment, the start-up condition may correspond to a start-up voltage parameter of the starter battery 124 of the EGS 120. More specifically, the BMS 144 may determine the voltage of the starter battery 124 by determining a load of the EGS 120 at start-up. For example, the load of the EGS 120 may be calculated by determining a current of the starter battery 124. As such, the processor 172 may generate a start-up voltage parameter trend for the starter battery 124 over multiple start-ups to indicate generator health. For example, as shown in FIGS. 4 and 5, example graphs 400, 500 depicting a start-up voltage parameter trend for the starter battery 124 of a properly operating EGS 120 (FIG. 4) and a poorly operating EGS 120 (FIG. 5) are illustrated according to the present disclosure. As shown, the start-up voltage parameter trend 402, 502 is monitored over a plurality of start-ups (e.g. five start-ups). More specifically, when the battery power device 140 voltage drops to a predetermined voltage, as indicated by lines 406 and 506, respectively, the BMS 144 sends a signal to the starter battery 124 of the EGS 120 to start up the engine of the EGS 120 as indicated by the sudden increase in voltage at each start-up. As shown in FIG. 4, the start-up voltage parameter for each start-up is above a threshold voltage parameter 404. Thus, the BMS 144 is configured to indicate that the EGS 120 health of FIG. 4 is “good.” In contrast, as shown in FIG. 5, the start-up voltage parameter trend 502 begins to drop below the threshold voltage parameter 504 (e.g. starting at start-up 4), therefore, in such an embodiment, the BMS 144 is configured to indicate that the EGS 120 health is “poor.”

It should be understood that the start-up voltage parameter may correspond to any suitable parameter that can be measured or monitored during start-up to indicate generator health, including but not limited to the voltage of the starter battery 124 at start-up or the current received by the starter battery 124 during start-up. For example, in certain embodiments, the start-up voltage parameter corresponds to a voltage drop or current drop of the starter battery 124 after the BMS has sent the start-command to the EGS 120. Thus, the BMS 144 is configured to determine the voltage of the starter battery 124 during start-up of the EGS 120. The BMS 144 can then compare the voltage drop of the starter battery 124 during the start-up event to a prior voltage drop of the starter battery 124 during a prior start-up. In various embodiments, if the voltage drop of the starter battery 124 is greater than a threshold voltage drop, then the EGS 120 health can be flagged as poor. In contrast, if the voltage drop of the starter battery 124 is less than the threshold voltage drop, then the EGS 120 health can be flagged as good.

In additional embodiments, the start-up condition may correspond to a start-up time lapse. For example, in certain embodiments, the start-up time lapse may be a time lapse between sending the start-up command and actual start-up of the engine-generator set. Alternatively, the start-up time lapse may be a predetermined monitoring time period, such as for example, a time period between before the start-up command is sent to the engine-generator set and the actual start-up of the engine-generator set. Thus, the BMS 144 can determine generator health by comparing the start-up time lapse with a threshold start-up time that indicates whether or not the EGS 120 is properly functioning. More specifically, in certain embodiments, the BMS 144 may determine the time lapse by determining the time between sending the start-up command and the time at which one or more of the batteries 142 of the battery power source 140 begin to receive a charge. In such embodiments, the BMS 144 can determine the health of the EGS 120 based on the comparison (i.e. between the time lapse and the actual start-up time) and the start-up voltage parameter trend. For example, if the time lapse between sending the start-up command and actual start-up of the EGS 120 is greater than the threshold start-up time, then the BMS 144 may indicate that the EGS 120 health is “poor”. In contrast, if the time lapse between sending the start-up command and actual start-up of the EGS 120 is less than the threshold start-up time, then the BMS 144 may indicate that the EGS 120 health is “good.” The term “good” or similar as used herein to describe EGS 120 health encompasses any suitable meaning of the term and generally indicates that the EGS 120 is operating properly, therefore, no maintenance is required. The term “poor” or similar as used herein to describe EGS 120 health encompasses any suitable meaning of the term and generally indicates that the generator is not operating properly. Thus, the EGS 120 may require additional service and/or maintenance or may need to be taken off-line, or similar.

The threshold start-up time is generally defined herein as the time it takes for the EGS 120 to start if the EGS 120 is exporting electricity. For example, in some embodiments, the threshold start-up time may be about 5 minutes. In further embodiments, the threshold start-up time may be more than 5 minutes or less than 5 minutes. In addition, the threshold start-up time may be a time range, such as e.g. from about 5 minutes to about 10 minutes. In another embodiment, a threshold voltage may be set in one or more of the batteries of the BMS 144 such that if one of the batteries operates below the threshold voltage, then the BMS 144 may indicate that the EGS 120 failed to start properly and/or that the EGS 120 health is “poor.” In contrast, if the one or more of the batteries of the BMS 144 operates above the threshold voltage, then the BMS 144 may indicate that the EGS 120 started properly and/or that the EGS 120 health is “good.” More specifically, if the start-up voltage parameter of one of the batteries is below the threshold voltage, then the EGS 120 did not start as designed, for example, when one or more of the batteries are on discharge, the BMS 144 issues a command to start at a predetermined voltage, the EGS 120 then fails to start and one or more of the BMS batteries continues to discharge, causing the voltage of one or more of the BMS batteries to decrease past the threshold voltage parameter (i.e. the EGS 120 failed to start). The BMS 144 can then issue an alert to a user that the EGS 120 failed to start.

In yet another embodiment, the start-up condition may correspond to a voltage of one of the batteries 142 of the battery power source 140 before sending the start-up command to the EGS 120. In such an embodiment, EGS 120 health can be determined by comparing the voltage of the battery power source 140 to a threshold voltage. More specifically, if the voltage of the battery power source 140 before the start-up command is sent to the EGS 120 is above a threshold voltage, then the EGS 120 health can be flagged as “good.” In contrast, if the voltage of the battery power source 140 before the start-up command is sent to the EGS 120 is below the threshold voltage, then the EGS 120 health can be flagged as “poor.”

In addition, as mentioned, EGS 120 health can be determined at least partially based on a fuel consumption trend of the EGS 120. For example, in one embodiment, the fuel consumption trend for the EGS 120 may be determined as a function of site load of the hybrid power system 150 during charge of the battery power source 140 and/or a total operating or run time of the EGS 120 for a predetermined time period. Thus, the fuel consumption trend may be compared to a threshold or actual fuel consumption records to determine if the fuel consumption trend is within predetermined bounds. As such, if the fuel consumption trend is equal to or less than the threshold fuel consumption, then the EGS 120 health can be flagged as “good.” Alternatively, if the fuel consumption trend is greater than the threshold fuel consumption, then the EGS 120 health can be flagged as “poor.” If the fuel consumption trend indicates that the EGS 120 is operating poorly, such indication is typically indicative of fuel leakage from the EGS 120 or fuel theft.

In still a further embodiment, the processor 172 is configured to determine and/or monitor the voltage drop during the discharge of the starter battery and a charge of the starter battery 124 and develop a voltage/charge trend of the starter 124 so as to infer EGS 120 starting health. In addition, the processor 172 is configured to determine whether the starter battery 120 initially begins to charge. If so, the processor 172 is configured to indicate to a user that the EGS 120 starter battery health is good. Alternatively, if the starter battery 124 voltage drops too much during the start and/or does not initially begin to charge, the processor 172 may indicate to the user that the EGS 120 health is poor. Further, if the starter battery 124 initially begins to charge, the processor 172 can continuously monitor the charge trend of the starter battery 124 so as to subsequently monitor EGS 120 health. Thus, if the starter battery 124 continues to charge, the processor 172 may indicate to the user that the EGS 120 health is good. Alternatively, if the starter battery 124 does not continue to charge, the processor 172 may indicate to the user that the EGS 120 health is poor. In certain embodiments, the processor 172 may determine the charge of the starter battery 124 by determining a load of the EGS 120.

Referring now to FIG. 6, a flow diagram of an example method 600 for monitoring health of a diesel generator is illustrated. At (602), the method 600 includes sending, by a battery management system, a start-up command to the engine-generator set, e.g. a diesel generator. At (604), the method 600 includes comparing a time lapse between the start-up command and actual start-up of the engine-generator set to a threshold start-up time. At (606), the method 600 includes monitoring, via the battery management system, a start-up voltage parameter of a starter battery of the engine-generator set over multiple start-ups to determine a start-up voltage parameter trend. At (608), the method 600 includes determining the health of the engine-generator set based on the comparison and the start-up voltage parameter trend.

Although specific features of various embodiments of the invention may be shown in some drawings and not in others, this is for convenience only. In accordance with the principles of the invention, any feature of a drawing may be referenced and/or claimed in combination with any feature of any other drawing.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A method for determining health of an engine-generator set of a hybrid power system comprising at least one battery power source, the method comprising:
sending, by a battery management system, a start-up command to the engine-generator set;
after sending the start-up command, determining at least one start-up condition of the hybrid power system;
generating a start-up condition trend based on a plurality of the start-up conditions of the hybrid power system over multiple start-ups; and,
determining the health of the engine-generator set based on a comparison of the start-up condition trend and a threshold start-up condition for the engine-generator set.

2. The method of claim 1, wherein the start-up condition of the hybrid power system comprises at least one of a start-up time lapse, a start-up voltage parameter of a starter battery of the engine-generator set, or a voltage of the at least one battery power source before sending the start-up command to the engine-generator set.

3. The method of claim 2, further comprising indicating to a user, by the battery management system, that the engine-generator set health is poor if the start-up time lapse is greater than a threshold start-up time and indicating to the user, by the battery management system, that the engine-generator set health is good if the start-up time lapse is less than the threshold start-up time.

4. The method of claim 2, further comprising indicating to a user, by the battery management system, that the engine-generator set health is good if the start-up voltage parameter is above a threshold voltage and indicating to the user, by the battery management system, that the engine-generator set health is poor if the start-up voltage parameter is below the threshold voltage.

5. The method of claim 2, further comprising indicating to a user, by the battery management system, that the engine-generator set health is good if the voltage of the starter battery of the engine-generator set, before sending the start-up command to the engine-generator set, is above a threshold voltage and indicating to a user, by the battery management system, that the engine-generator set health is poor if the voltage of the starter battery of the engine-generator set, before sending the start-up command to the engine-generator set, is below the threshold voltage.

6. The method of claim 2, wherein determining the start-up time lapse further comprises determining a time between sending the start-up command and a time at which one or more batteries of the battery management system begins receiving a charge.

7. The method of claim 1, wherein the at least one battery power source comprises one or more sodium nickel chloride batteries.

8. A method for determining health of an engine-generator set of a hybrid power system comprising at least one battery power source, the method comprising:
sending, by a battery management system, a charging command to the engine-generator set;
determining a voltage condition of a starter battery of the engine-generator set;
monitoring, via a battery management system, a voltage trend of the starter battery based on a plurality of voltage conditions of the starter battery over a predetermined time period; and,
determining the health of the engine-generator set based on the voltage trend of the starter battery.

9. The method of claim 8, wherein, after sending the charging command to the engine-generator set, the method further comprises determining whether the starter battery of the engine-generator set initially begins to charge.

10. The method of claim 9, wherein, if the starter battery of the engine-generator set initially begins to charge, the method further comprises indicating to a user, by the battery management system, that the engine-generator set health is good, and wherein, if the starter battery set does not initially begin to charge, the method further comprises indicating to the user, by the battery management system, that the engine-generator set health is poor.

11. The method of claim 9, wherein, if the starter battery of the engine-generator set initially begins to charge, the method further comprises continuously monitoring the charge trend of the starter battery of the engine-generator set.

12. The method of claim 11, wherein if the starter battery of the engine-generator set continues to charge, the method further comprises indicating to a user, by the battery management system, that the engine-generator set health is good, and wherein, if the starter battery does not continue to charge, the method further comprises indicating to the user, by the battery management system, that the engine-generator set health is poor.

13. The method of claim 8, wherein determining the voltage condition of the starter battery further comprises determining a load of the engine-generator set.

14. The method of claim 8, further comprising monitoring an energy storage capacity of the battery power source.

15. The method of claim 8, wherein the at least one battery power source comprises one or more sodium nickel chloride batteries.

16. A method for determining health of an engine-generator set of a hybrid power system comprising at least one battery power source, the method comprising:
sending, by a battery management system, a start-up command to the engine-generator set;
determining a fuel consumption trend of the engine-generator set as a function of at least one of a site load for the hybrid power system during charge of the battery power source or a total operating time of the engine-generator set for a predetermined time period; and,
determining the health of the engine-generator set based on the fuel consumption trend.

17. The method of claim 16, further comprising comparing the fuel consumption trend to a threshold fuel consumption value.

18. The method of claim 17, wherein if the fuel consumption trend is equal to or less than the threshold fuel consumption value, then the method further comprises indicating to a user, by the battery management system, that the engine-generator set health is good, and wherein, if the fuel consumption trend is greater than the threshold fuel consumption value, the method further comprises indicating to the user, by the battery management system, that the engine-generator set health is poor.

19. The method of claim 18, wherein indicating, by the battery management system, that the engine-generator set is poor, implies at least one of fuel leakage from the engine-generator set or fuel theft.

20. The method of claim 16, wherein the at least one battery power source comprises one or more sodium nickel chloride batteries.
